(19) United States
(12) Patent Application Publication
(10) Pub. No.: US 2026/0040975 A1
(43) Pub. Date: Feb. 5, 2026

(54) SEMICONDUCTOR PACKAGE AND METHOD OF FABRICATING THE SAME

(71) Applicant: Samsung Electronics Co., Ltd., Suwon-si (KR)

(72) Inventors: Wooyoung Kim, Suwon-si (KR); Kwonjin Kim, Suwon-si (KR); Sangjin Baek, Suwon-si (KR); Gongje Lee, Suwon-si (KR); Yeonho Jang, Suwon-si (KR)

(21) Appl. No.: 19/063,766

(22) Filed: Feb. 26, 2025

(30) Foreign Application Priority Data
Jul. 31, 2024 (KR) 10-2024-0102027

(51) Int. Cl. H01L 23/498; H01L 21/48; H01L 23/00; H01L 23/367; H01L 23/538; H01L 25/16; H10B 80/00; H10D 80/30

(52) U.S. Cl. CPC H01L 23/49838; H01L 23/3672; H01L 23/49866; H01L 23/5385; H01L 24/16; H01L 25/16; H10B 80/00; H10D 80/30; H01L 21/4853; H01L 24/13; H01L 24/32; H01L 24/73; H01L 2224/13111; H01L 2224/13124; H01L 2224/13139; H01L 2224/16146; H01L 2224/16227; H01L 2224/32145; H01L 2224/73204; H01L 2225/06513; H01L 2225/06517; H01L 2225/06544; H01L 2225/06548; H01L 2225/06589; H01L 2924/1431

(57) ABSTRACT

A semiconductor package includes a first redistribution substrate comprising a plurality of upper substrate pads including a first upper substrate pad;, a first semiconductor device mounted on the first redistribution substrate and connected to the first redistribution substrate through bonding of the first upper substrate pad to a first connection terminal, a plurality of conductive through posts disposed on the first redistribution substrate outside of the first semiconductor device from a plan view, and a second redistribution substrate disposed on the first semiconductor device and the plurality of conductive through posts. The first upper substrate pad has a convex upper surface and has a coupling roughness formed on an upper surface thereof.

### CROSS-REFERENCE TO RELATED APPLICATION

This application is based on and claims priority under 35 U.S.C. § 119 to Korean Patent Application No. 10-2024-0102027, filed on Jul. 31, 2024, in the Korean Intellectual Property Office, the disclosure of which is incorporated by reference herein in its entirety.

### BACKGROUND

The inventive concept relates to a semiconductor package, and more particularly, to a semiconductor package including a redistribution substrate below a semiconductor chip and a method of fabricating the same.

In accordance with the rapid development of the electronics industry and the needs of users, electronic devices are becoming more compact and lightweight. Accordingly, semiconductor packages used in electronic devices are also becoming more compact and lightweight. In addition, semiconductor packages typically require high performance and large capacity along with size reduction and weight reduction. On the other hand, as such semiconductor packages have high performance and large capacity, the power consumption of the semiconductor packages has increased and the reliability issue has grown. Accordingly, the importance of heat dissipation characteristics and reliability of semiconductor packages along with size reduction and performance improvement of semiconductor packages is increasing.

### SUMMARY

Aspects of the inventive concept provide a semiconductor package, which is capable of improving reliability and yield by increasing adhesion between a semiconductor chip and a redistribution substrate, and a method of fabricating the same.

In addition, the technical objectives of the inventive concept are not limited to those described above, and other objectives that are not mentioned herein will be clearly understood from the following description by those of ordinary skill in the art.

According to an aspect of the inventive concept, a semiconductor package includes: a first redistribution substrate comprising a plurality of upper substrate pads including a first upper substrate pad; a first semiconductor device mounted on the first redistribution substrate and connected to the first redistribution substrate through bonding of the first upper substrate pad to a first connection terminal; a plurality of conductive through posts disposed on the first redistribution substrate outside of the first semiconductor device from a plan view; and a second redistribution substrate disposed on the first semiconductor device and the plurality of conductive through posts. The first upper substrate pad has a convex upper surface and has a coupling roughness formed on an upper surface thereof.

According to an aspect of the inventive concept, a semiconductor package includes: a first redistribution substrate comprising a plurality of upper substrate pads; a first semiconductor device mounted on the first redistribution substrate and electrically connected to the first redistribution substrate through a first connection terminal disposed on the first redistribution substrate; a conductive through post disposed on the first redistribution substrate to be adjacent to the first semiconductor device; a sealant that seals the first semiconductor device and the conductive through post on the first redistribution substrate; a second redistribution substrate disposed on the first semiconductor device, the conductive through post, and the sealant; and a second semiconductor device mounted on the second redistribution substrate. The plurality of upper substrate pads comprise a first upper substrate pad bonded to the first connection terminal and a second upper substrate pad bonded to the conductive through post, and the first upper substrate pad has a convex upper surface and has a coupling roughness formed on an upper surface thereof.

According to an aspect of the inventive concept, a semiconductor package includes: a first redistribution substrate comprising a plurality of upper substrate pads including a first upper substrate pad; a first semiconductor device mounted on the first redistribution substrate and connected to the first redistribution substrate through bonding of the first upper substrate pad to a first connection terminal; a conductive through post disposed on the first redistribution substrate outside of the first semiconductor device as viewed from a plan view; a second redistribution substrate disposed on the first semiconductor device and the conductive through post; and a second semiconductor device mounted on the second redistribution substrate. The first redistribution substrate comprises a substrate body, multilayer redistribution lines within the substrate body, and the plurality of upper substrate pads, and the first upper substrate pad is connected to an uppermost redistribution line among the multilayer redistribution lines, has a convex upper surface, and has a coupling roughness formed on an upper surface thereof.

According to an aspect of the inventive concept, a method of fabricating a semiconductor package includes: forming a first redistribution substrate; forming a plurality of conductive through posts on the first redistribution substrate; mounting a first semiconductor device on the first redistribution substrate through a plurality of first connection terminals; and forming a second redistribution substrate on the first semiconductor device and the plurality of conductive through posts. In the forming of the first redistribution substrate, a plurality of upper substrate pads each having a convex upper surface and having a coupling roughness formed on an upper surface thereof is formed on an upper surface of the first redistribution substrate, and in the mounting of the first semiconductor device, the plurality of first connection terminals are bonded respectively to the plurality of upper substrate pads.

According to an aspect of the inventive concept, the first redistribution substrate comprises a substrate body, multilayer redistribution lines within the substrate body, and the plurality of upper substrate pads, and the forming of the first redistribution substrate comprises: forming a first through hole in the substrate body to expose a portion of an uppermost redistribution line among the multilayer redistribution lines; forming a photoresist (PR) pattern on the substrate body, the PR pattern having a second through hole overlapping the first through hole; forming a first upper substrate pad of the plurality of upper substrate pads through a plating process within the first and second through holes; and forming the coupling roughness through a chemical treatment on the upper surface of the first upper substrate pad. According to an aspect of the inventive concept, the first upper substrate pad comprises a copper (Cu) layer, a nickel (Ni) layer, and a gold (Au) layer, which are sequentially stacked in an upward direction toward the first semiconductor device, and in the forming of the first upper substrate pad, the Cu layer is formed to have a convex upper surface through a via-filling process.

According to an aspect of the inventive concept, before the forming of the second redistribution substrate, a sealant is formed on the first redistribution substrate to cover the plurality of conductive through posts and the first semiconductor device; and an upper surface of each of the plurality of conductive through posts is exposed by removing an upper portion of the sealant.

According to an aspect of the inventive concept, after the forming of the second redistribution substrate, a second semiconductor device is mounted on the second redistribution substrate, wherein the first semiconductor device comprises a logic chip, and the second semiconductor device comprises a memory chip or a memory package.

### BRIEF DESCRIPTION OF THE DRAWINGS

Embodiments will be more clearly understood from the following detailed description taken in conjunction with the accompanying drawings in which:

FIGS. 1A and 1B are respectively a cross-sectional view and an enlarged view of a semiconductor package according to an embodiment;

FIGS. 2A and 2B are enlarged views of upper substrate pads of a redistribution substrate of FIG. 1B;

FIGS. 3A to 3C are cross-sectional views to describe the difference in shape between an upper substrate pad of a semiconductor package of a comparative example and upper substrate pads of FIGS. 2A and 2B;

FIGS. 4A to 4C are cross-sectional views of semiconductor packages according to embodiments;

FIGS. 5A and 5B are cross-sectional views of semiconductor packages according to embodiments;

FIGS. 6A to 6C are cross-sectional views illustrating a structure of a semiconductor element in the semiconductor package of FIGS. 5A or 5B in more detail;

FIGS. 7A to 7F are cross-sectional views schematically illustrating a method of fabricating a semiconductor package, according to an embodiment;

FIGS. 8A to 8D are cross-sectional views illustrating a process of forming a first redistribution substrate of FIG. 7A in more detail; and

FIGS. 9A to 9D are cross-sectional views illustrating a process of forming a through post of FIG. 7B in more detail.

### DETAILED DESCRIPTION OF THE EMBODIMENTS

Hereinafter, embodiments will be described in detail with reference to the accompanying drawings. The same elements in the drawings are denoted by the same reference numerals, and redundant descriptions thereof are omitted.

Throughout the specification, when a component is described as “including” a particular clement or group of elements, it is to be understood that the component is formed of only the clement or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

Terms such as “about” or “approximately” may reflect amounts, sizes, orientations, or layouts that vary only in a small relative manner, and/or in a way that does not significantly alter the operation, functionality, or structure of certain elements.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

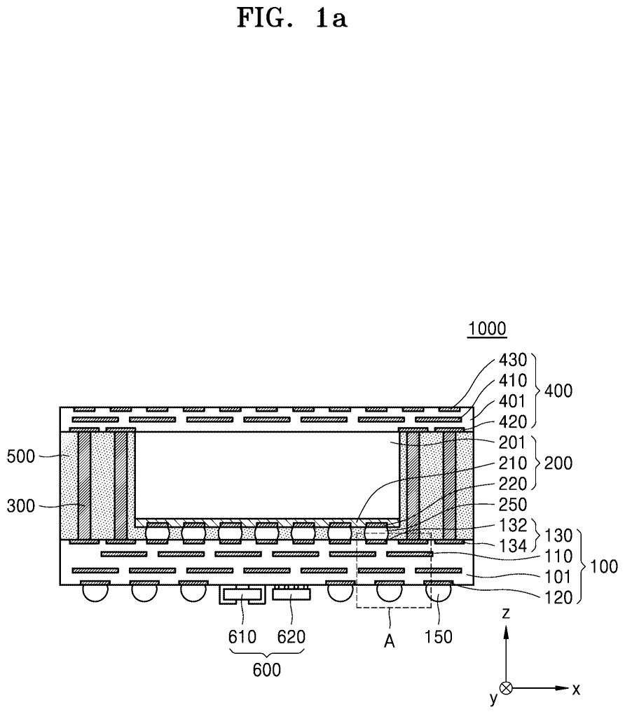

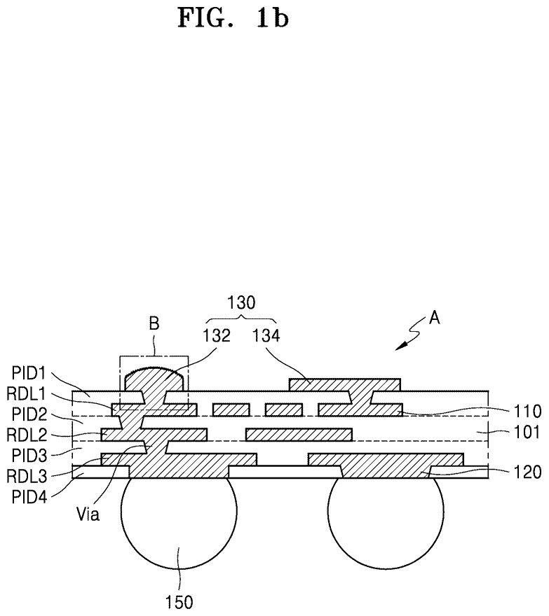

FIGS. 1A and 1B are respectively a cross-sectional view and an enlarged view of a semiconductor package 1000 according to an embodiment. FIG. 1B is an enlarged view of a region A of FIG. 1A.

Referring to FIGS. 1A and 1B, the semiconductor package 1000 of the present embodiment may include a first redistribution substrate 100, a first semiconductor element 200, a through post 300, a second redistribution substrate 400, a sealant 500, and a passive element 600. Various items labeled and described in the singular are provided in plural, as can be seen from FIGS. 1A and 1B and other figures.

The first redistribution substrate 100 may be disposed below the first semiconductor clement 200 and may redistribute a chip pad 220 of the first semiconductor element 200 to an external area of the first semiconductor element 200. For example, the first redistribution substrate 100 may include a first substrate body 101, first redistribution lines 110, a lower substrate pad 120, and an upper substrate pad 130.

The various pads of a device described herein may be conductive terminals connected to internal wiring of the device, and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be provided on or near an external surface of the device to promote an electrical connection to a further terminal, such as a bump or solder ball, and/or an external wiring.

The first substrate body 101 may include polymer. For example, the first substrate body 101 may include a photo-imageable dielectric (PID) resin and may further include an inorganic filler. However, the material of the first substrate body 101 is not limited to the materials described above. For example, the first substrate body 101 may include polyimide isoindro quirazorindione (PIQ), polyimide (PI), polybenzoxazole (PBO), or the like.

As illustrated in FIG. 1B, the first substrate body 101 may have a multilayer structure as the first redistribution line 110 has a multilayer structure. For example, the first substrate body 101 may include first to fourth insulating layers PID1 to PID4. However, the number of layers of the first substrate body 101 is not limited to four. In FIG. 1A, for convenience, the first substrate body 101 is illustrated as a single-layer structure. On the other hand, the first to fourth insulating layers PID1 to PID4 may all include the same material. However, in some embodiments, the fourth insulating layer PID4, which is the lowermost layer, may have a material or a characteristic that is different from that of each of the first to third insulating layers PID1 to PID3. In some embodiments, the fourth insulating layer PID4 may be a protective layer or a passivation layer. The fourth insulating layer PID4 may protect the first redistribution substrate 100 and the semiconductor package 1000 from chemical and physical damage.

The first redistribution line 110 may be disposed in a multilayer structure within the first substrate body 101, as illustrated in FIG. 1A. For example, the first redistribution line 110 may include first to third redistribution layers RDL1 to RDL3. However, the number of layers of the first redistribution lines 110 is not limited to three. It may be confirmed from FIG. 1B that first redistribution lines 110 adjacent to each other in the vertical direction, i.e., in the z direction, may be connected to each other through vertical vias. Each of the first redistribution lines 110 and the vertical vias may include or be, for example, copper (Cu). However, the material of each of the redistribution lines 110 and the vertical vias is not limited to Cu.

The lower substrate pads 120 may be disposed on the lower surface of the first substrate body 101. In addition, each lower substrate pad 120 may be connected to a lowermost first redistribution line 110, for example, the third redistribution layer RDL3, among the first redistribution lines 110. For example, the lower substrate pads 120 may pass through the fourth insulating layer PID4 of the first substrate body 101 and be connected to the third redistribution layer RDL3. An external connection terminal 150 may be disposed on each lower substrate pad 120. In some embodiments, some first redistribution lines 110 may be formed as the lower substrate pads 120, and under bump metallurgy (UBM) may be disposed between the lower substrate pads 120 and the external connection terminals 150 and may pass through the fourth insulating layer PID4.

The external connection terminals 150 may be disposed on the lower portion of the chip corresponding to the lower surface of the first semiconductor element 200 and on the outer portion of the chip extending outward from the lower portion of the chip. Ultimately, the first redistribution substrate 100 may redistribute the chip pads 220 of the first semiconductor element 200 to a wider area than the lower surface of the first semiconductor element 200 through the first redistribution lines 110. A package structure in which the external connection terminals 150 are widely disposed up to the outer portion of the chip beyond the lower portion of the chip of the first semiconductor element 200 is referred to as a fan-out (FO) package structure. On the other hand, in contrast to the FO package structure, a package structure in which the external connection terminals 150 are disposed only on the lower portion of the chip corresponding to the lower surface of the first semiconductor element 200 (e.g., to overlap the lower surface of the first semiconductor element 200 as viewed from a plan view) is referred to as a fan-in (FI) package structure.

The external connection terminals 150 may connect the semiconductor package 1000 to a package substrate of an external system or a main board of an electronic device such as a mobile device. The external connection terminals 150 may include at least one of conductive materials, such as solder, tin (Sn), silver (Ag), copper (Cu), and aluminum (Al). However, the material of the external connection terminals 150 is not limited to the materials described above. In some embodiments, the external connection terminals 150 include at least one of solder, tin (Sn), silver (Ag), and aluminum (Al).

The upper substrate pads 130 may be disposed on the upper surface of the first substrate body 101. In addition, the upper substrate pads 130 may be connected to the uppermost first redistribution lines 110, for example, the first redistribution layer RDL1, among the first redistribution lines 110. For example, the upper substrate pads 130 may pass through at least a portion of the first insulating layer PID1 of the first substrate body 101 and be connected to the first redistribution layer RDL1.

The upper substrate pads 130 may include first upper substrate pads 132 and second upper substrate pads 134. First connection terminals 250 of the first semiconductor element 200 may be connected to the first upper substrate pads 132. The through posts 300 may be connected to the second upper substrate pads 134. The size of each first upper substrate pad 132 may be smaller than the size of each second upper substrate pad 134. The size may refer to the area on the x-y plane. In some embodiments, the first connection terminals 250 include at least one of solder, tin (Sn), silver (Ag), and aluminum. (Al).

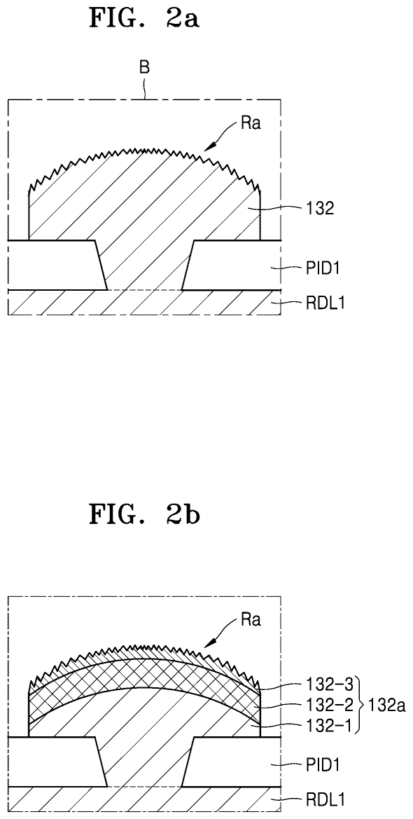

As illustrated in FIG. 1B, the upper surface of each first upper substrate pad 132 may have an upwardly convex structure. In some embodiments, each upper substrate pad 132 may have an over-hang structure, in which the pad overhangs a portion of the first insulating layer PID1 to vertically overlap a portion of the first insulating layer PID1. In addition, a coupling roughness Ra may be formed on the upper surface of each first upper substrate pad 132. For reference, FIG. 1B illustrates the shape of the first upper substrate pad 132 before the first connection terminal 250 of the first semiconductor element 200 is coupled to the first upper substrate pad 132. In practice, after the first connection terminal 250 and the first upper substrate pad 132 are coupled to each other, the upper surface of the first upper substrate pad 132 may not be as significantly convex. For example, after the first connection terminal 250 and the first upper substrate pad 132 are coupled to each other, a portion of the central portion of the upper surface of the first upper substrate pad 132 may be slightly higher than the outer portion of the upper surface of the first upper substrate pad 132. A more specific structure of the first upper substrate pad 132 is described in more detail below with reference to FIGS. 2A and 2B.

On the other hand, the second upper substrate pad 134 may have a similar structure to a general substrate pad. For example, the upper surface of the second upper substrate pad 134 may have a flat shape. However, in some embodiments, the upper surface of the second upper substrate pad 134 may have a convex shape. In addition, in some embodiments, a coupling roughness may be formed on the upper surface of the second upper substrate pad 134.

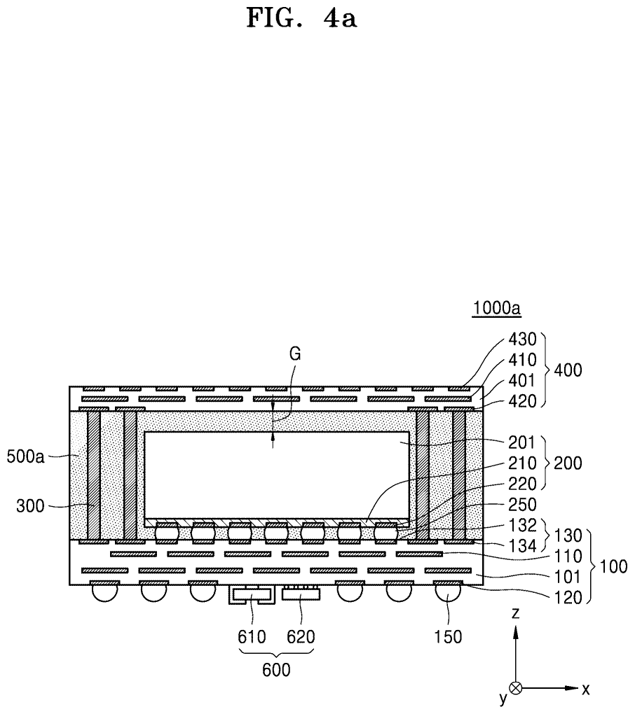

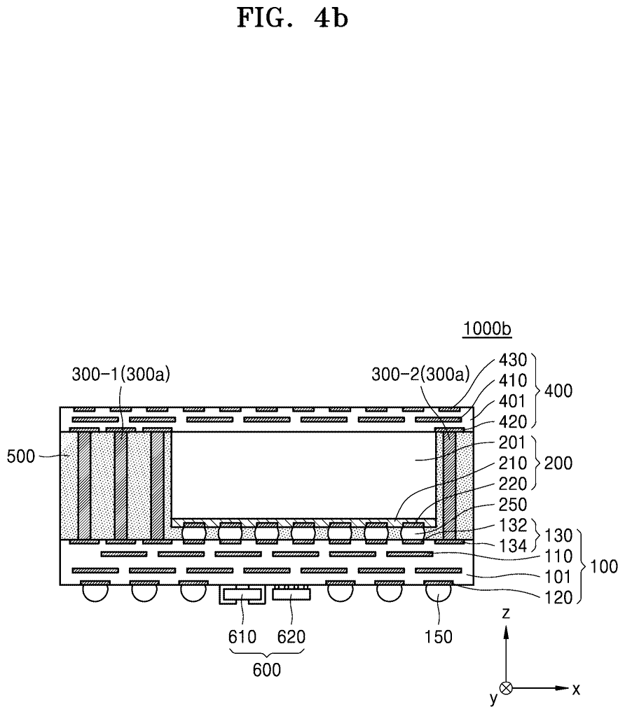

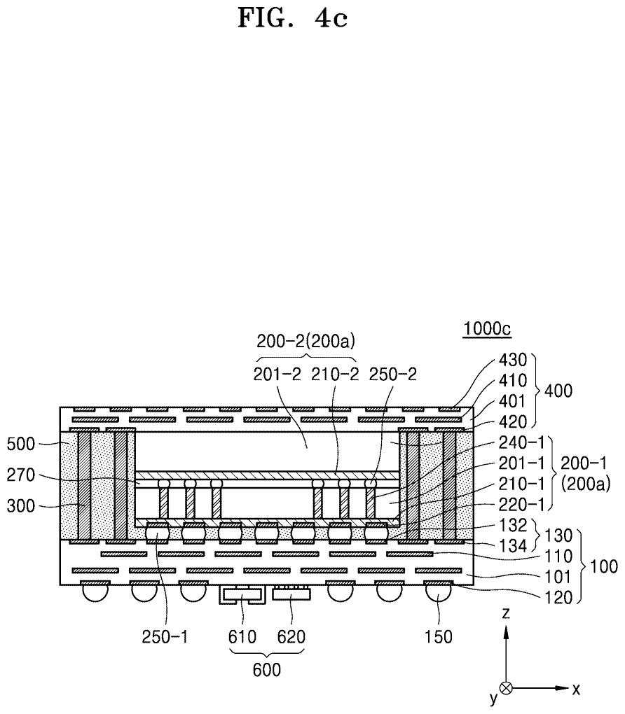

The first semiconductor element 200 may be a semiconductor device mounted on the first redistribution substrate 100 through the first connection terminals 250. As illustrated in FIG. 1A, the first semiconductor element 200 may be disposed in the central portion of the first redistribution substrate 100. For example, the first semiconductor element 200 may be disposed in the central portion of the first redistribution substrate 100 in the x direction and the y direction. However, the disposition position of the first semiconductor element 200 is not limited thereto. For example, the first semiconductor element 200 may be shifted to one side in the x direction and/or the y direction on the first redistribution substrate 100. The semiconductor package structure in which the first semiconductor element 200 is shifted is described in more detail below with reference to FIG. 4B.

The first semiconductor element 200 may be a semiconductor device such as a semiconductor chip (e.g., a die formed from a wafer), plurality of stacked semiconductor chips, or semiconductor package. For example, the semiconductor element may include or be a logic semiconductor chip. The logic semiconductor chip may include a plurality of logic elements therein. The logic elements are elements that perform a variety of signal processing and may include, for example, an AND, an OR, a NOT, flip-flops, etc. The first semiconductor element 200 may include or be an application processor (AP), a microprocessor, a central processing unit (CPU), a graphics processing unit (GPU), a neural processing unit (NPU), a controller, or an application specific integrated circuit (ASIC). For example, the first semiconductor element 200 may constitute a GPU/CPU/NPU/system-on-chip (SOC) chip, etc. The semiconductor package 1000 may be divided into a server-oriented semiconductor device or a mobile-oriented semiconductor device according to the type of the first semiconductor element 200. However, the first semiconductor element 200 is not limited to the logic semiconductor chip. For example, in some embodiments, the first semiconductor element 200 may include a memory semiconductor chip.

According to some embodiments, the first semiconductor element 200 may include a substrate 201, an active layer 210, and chip pads 220. The substrate 201 may constitute the body of the first semiconductor element 200 and may be based on a silicon wafer. The active layer 210 may be disposed on the lower portion of the substrate 201. The active layer 210 may include an integrated circuit layer on which active elements such as transistors are disposed and a multi-wiring layer disposed on the integrated circuit layer.

The chip pads 220 may be disposed on the lower surface of the active layer 210. The chip pads 220 may be connected to the multi-wiring layer of the active layer 210. The first connection terminals 250 may be disposed on the chip pads 220. Accordingly, the first connection terminals 250 may be connected to the multi-wiring layer of the active layer 210 through the chip pads 220.

The first semiconductor element 200 may be mounted on the first redistribution substrate 100 in a flip-chip structure. Accordingly, the lower surface of the first semiconductor element 200, for example, the lower surface of the active layer 210, may be an active surface. The lower surface of the active layer 210 may face the first redistribution substrate 100. In addition, the upper surface of the first semiconductor element 200, for example, the upper surface of the substrate 201, may be an inactive surface, and the upper surface of the substrate 201 may face the second redistribution substrate 400.

As illustrated in FIG. 1A, the upper surface of the first semiconductor element 200 may contact the lower surface of the second redistribution substrate 400. In other words, the sealant 500 may not be disposed between the first semiconductor element 200 and the second redistribution substrate 400. However, in some embodiments, the sealant 500 may be disposed between the first semiconductor element 200 and the second redistribution substrate 400. The semiconductor package structure in which the sealant 500 is disposed between the first semiconductor element 200 and the second redistribution substrate 400 is described in more detail below with reference to FIG. 4A.

The through posts 300 may be conductive through posts disposed between the first redistribution substrate 100 and the second redistribution substrate 400. As the sealant 500 is disposed between the first redistribution substrate 100 and the second redistribution substrate 400, the through posts 300 may extend to pass through the sealant 500. The through posts 300 may electrically connect the first redistribution substrate 100 to the second redistribution substrate 400. For example, the lower surface of each through post 300 may be connected to an upper substrate pad 130 of the first redistribution substrate 100, and the upper surface of each through post 300 may be connected to a lower substrate pad 420 of the second redistribution substrate 400. The through posts 300 may be disposed outside of the semiconductor element 200 from a plan view to surround the semiconductor element 200 from a plan view, for example, to be disposed on all four sides of the semiconductor element 200.

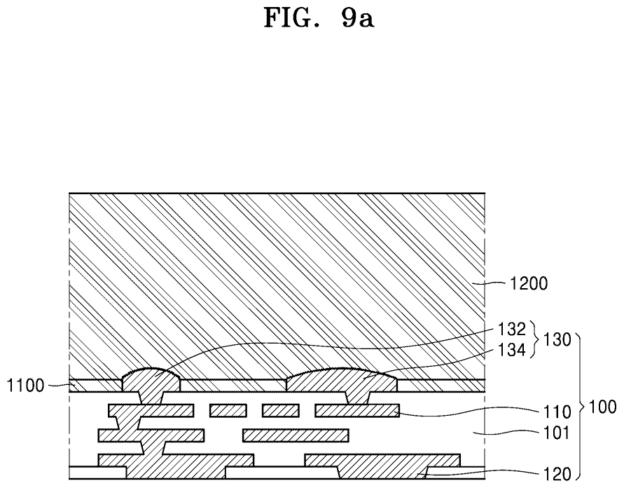

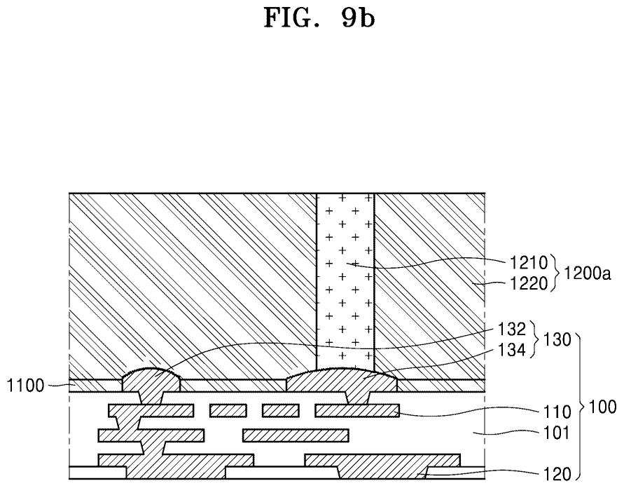

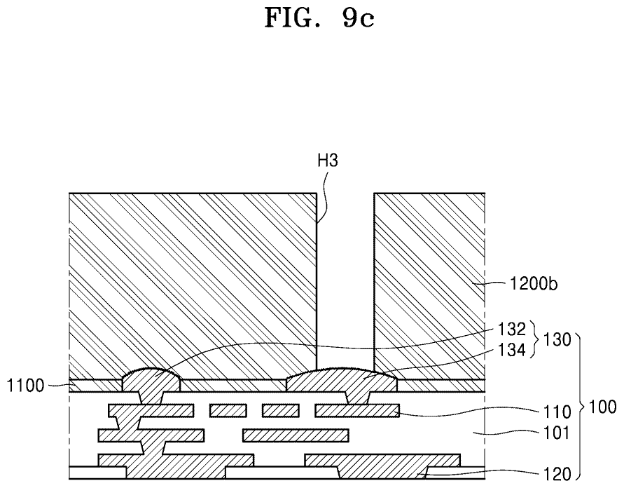

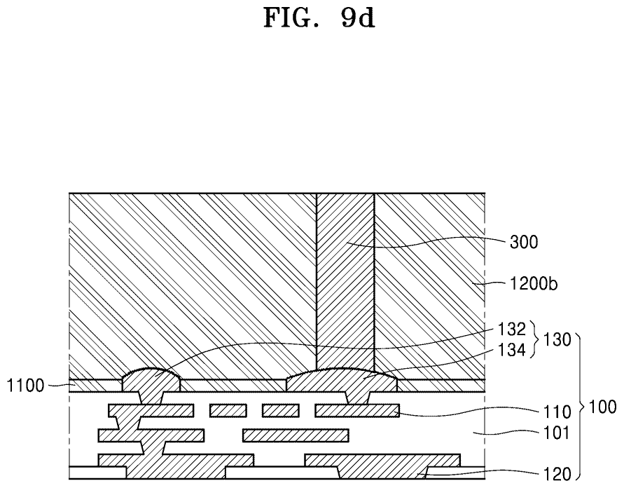

The through posts 300 may include or may be Cu. Accordingly, the through post 300 may also be referred to as a Cu post. However, the material of the through post 300 is not limited to Cu. As described above, the through posts 300 may be disposed on the second upper substrate pads 134. The through posts 300 may be formed through plating by using the second upper substrate pads 134 as a seed layer. The method of forming the through posts 300 is described in more detail below with reference to FIGS. 9A to 9D.

The second redistribution substrate 400 may be disposed on the first semiconductor element 200, the through posts 300, and the sealant 500. The second redistribution substrate 400 may have a similar structure to the first redistribution substrate 100. For example, the second redistribution substrate 400 may include a second substrate body 401, second redistribution lines 410, lower substrate pads 420, and upper substrate pads 430. The second substrate body 401, the second redistribution lines 410, the lower substrate pads 420, and the upper substrate pads 430 may have respectively the same formation, material, and structure as the first substrate body 101, the first redistribution lines 110, the lower substrate pad 120, and the upper substrate pad 130 of the first redistribution substrate 100, which have been described above.

On the other hand, as illustrated in FIG. 1A, the number of layers of the second redistribution lines 410 may be less than the number of layers of the first redistribution lines 110. Accordingly, the thickness of the second substrate body 401 or the second redistribution substrate 400 may be less than the thickness of the first substrate body 101 or the first redistribution substrate 100. However, in some embodiments, the number of layers of the second redistribution line 410 may be equal to the number of layers of the first redistribution line 110, and thus, the thickness of the second redistribution substrate 400 may be substantially equal to the thickness of the first redistribution substrate 100.

The second redistribution lines 410 of the second redistribution substrate 400 may be connected to the first semiconductor element 200 and the external connection terminals 150 through the through posts 300 and the first redistribution lines 110 of the first redistribution substrate 100. In some embodiments, the uppermost insulating layer of the second substrate body 401 of the second redistribution substrate 400 may have a material or a characteristic that is different from that of the lower insulating layers. For example, the uppermost insulating layer of the second substrate body 401 may be a protective layer or a passivation layer. The uppermost insulating layer of the second substrate body 401 may protect the second redistribution substrate 400 and the semiconductor package 1000 from chemical and physical damage.

The sealant 500 may be disposed between the first redistribution substrate 100 and the second redistribution substrate 400. The sealant 500 may cover and seal the side surfaces of the first semiconductor element 200 and the through posts 300. In addition, as illustrated in FIG. 1A, the sealant 500 may fill a space between the first semiconductor element 200 and the first redistribution substrate 100 and between the first connection terminals 250 on the lower surface of the first semiconductor element 200. However, in some embodiments, an underfill may be filled between the first semiconductor element 200 and the first redistribution substrate 100, and the sealant 500 may cover the side surface of the underfill.

The sealant 500 may be an encapsulation layer and may include or be an insulating material, for example, a thermosetting resin such as epoxy resin or a thermoplastic resin such as PI. In addition, or alternatively, the sealant 500 may include a resin including a reinforcing material, such as an inorganic filler, in a thermosetting resin or a thermoplastic resin, for example, Ajinomoto build-up film (ABF), FR-4, or bismaleimide triazine (BT) resin. On the other hand, the sealant 500 may include a molding material such as an epoxy molding compound (EMC) or a photosensitive material such as a photo-imageable encapsulant (PIE). However, the material of the sealant 500 is not limited to the materials described above.

One or more passive elements 600 may be disposed on the lower surface of the first redistribution substrate 100. In some embodiments, a passive element 600 may be disposed on the upper surface of the first redistribution substrate 100 or may be disposed inside the first redistribution substrate 100. In addition, a passive element 600 may be disposed on the lower surface or the upper surface of the second redistribution substrate 400 or may be disposed inside the second redistribution substrate 400. The passive elements 600 may include two-terminal elements, such as resistors, inductors, or capacitors. In the semiconductor package 1000 of the present embodiment, the passive elements 600 may be or include a multi-layer ceramic capacitor (MLCC) 610 and a Si capacitor 620.

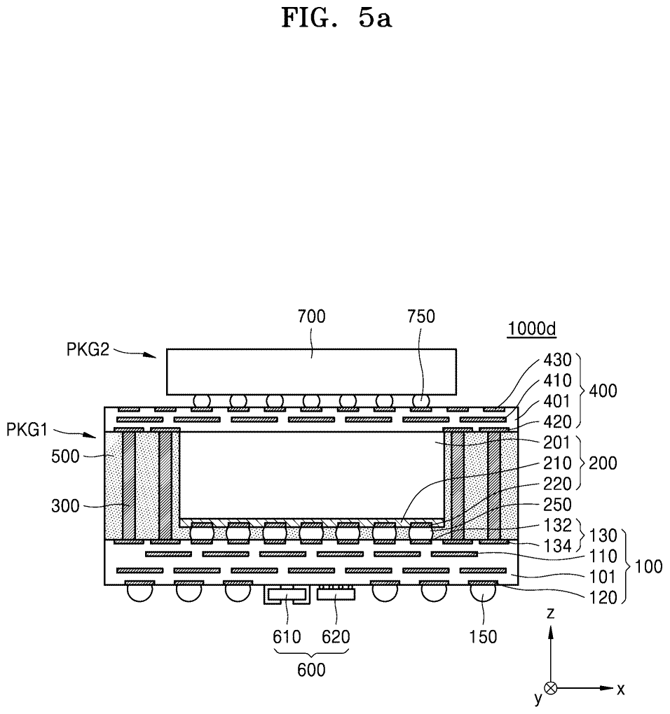

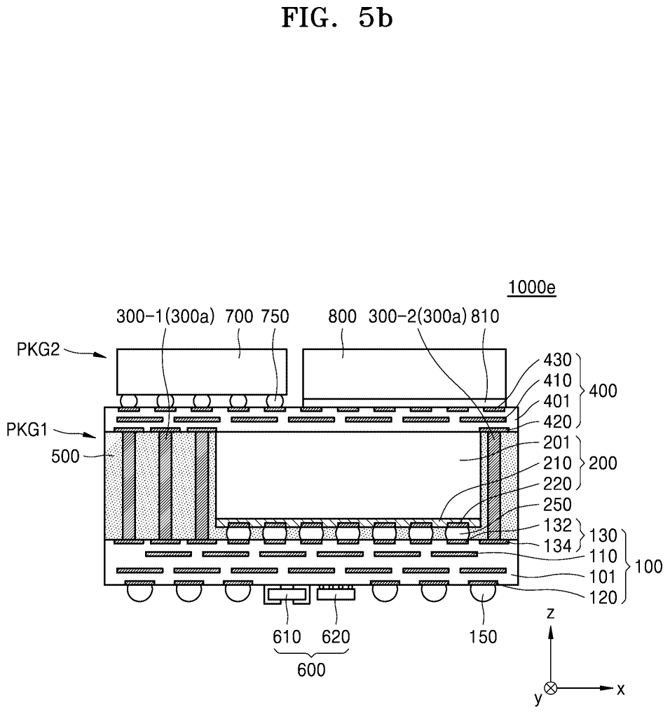

At least one semiconductor element may be stacked on the upper surface of the second redistribution substrate 400. In some embodiments, at least one semiconductor element may have an upper package structure and may be stacked on the second redistribution substrate 400. The structure of the semiconductor package in which the upper package is stacked on the second redistribution substrate 400 may correspond to a package on package (POP) structure. The semiconductor package having the POP structure is described in more detail below with reference to FIGS. 5A and 5B.

In the semiconductor package 1000 of the present embodiment, the first redistribution substrate 100 may include the upper substrate pads 130, and the first upper substrate pads 132 of the upper substrate pads 130 connected to the first connection terminals 250 of the first semiconductor element 200 may have a structure with a convex upper surface. In addition, a coupling roughness Ra may be formed on the upper surface of the first upper substrate pads 132. As described above, because each first upper substrate pad 132 has a structure with a convex upper surface and the coupling roughness Ra on the upper surface thereof, the adhesion between the first upper substrate pads 132 and the first connection terminals 250 may be greatly improved. Accordingly, a non-wet defect between the first connection terminals 250 of the first semiconductor element 200 and the first upper substrate pads 132 of the first redistribution substrate 100 may be prevented and warpage of the first semiconductor clement 200 may be minimized. As a result, the semiconductor package 1000 of the present embodiment may greatly contribute to improving the reliability of the semiconductor package and increasing the yield of the semiconductor package.

FIGS. 2A and 2B are enlarged views of the upper substrate pads of the redistribution substrate of FIG. 1B. Elements described above with reference to FIGS. 1A and 1B are briefly described or omitted.

Referring to FIG. 2A, in the semiconductor package 1000 of the present embodiment, a first upper substrate pad 132 of the upper substrate pads 130 of the first redistribution substrate 100 may be coupled to a first connection terminal 250 of the first semiconductor element 200. The first upper substrate pad 132 may include or may be a metal layer. For example, the first upper substrate pad 132 may include or may be formed of Cu. In some embodiments, the first upper substrate pads 132 include only Cu, or include one or more metals only, and do not include a solder, Sn, Ag, or Al. However, the material of the first upper substrate pad 132 is not limited to Cu.

The first upper substrate pad 132 may have a convex upper surface. Specifically, the first upper substrate pad 132 may include a pillar having a truncated reverse conical shape and a circular cap (e.g., a dome-shaped cap, which may be a plate having a dome-shaped upper surface and having a circular shape when viewed in a plan view) disposed on the pillar. The convex upper surface may mean that the central portion is higher than the outer portion on the x-y plane. In addition, as illustrated in FIG. 2A, the coupling roughness Ra may be formed on the upper surface of the first upper substrate pad 132. The surface roughness of the upper surface of the first upper substrate pad 132 may be, for example, about 0.05 μm to about 0.07 μm. However, the surface roughness of the upper surface of the first upper substrate pad 132 is not limited to the numerical range described above. The coupling roughness may be a roughness greater than an incidental roughness of surfaces of redistribution lines or surfaces of other conductive components formed of one or more metals and that do not undergo a roughness treatment.

In addition, the first upper substrate pad 132 having the roughness illustrated in FIG. 2A may be in a state before the first upper substrate pad 132 is coupled to the first connection terminal 250 of the first semiconductor element 200. When the first semiconductor clement 200 is mounted through the first connection terminal 250, a thermal compression bonding (TCB) and reflow process may be performed. Accordingly, the first upper substrate pad 132 may be pressed by the first connection terminal 250 so that the upper surface of the first upper substrate pad 132 does not have a shape with a constant curvature, as illustrated in FIG. 2A, and in practice, at least a part of the central portion thereof may have a shape such that a thickness at the central portion, and a height of a surface at the central portion is slightly larger or higher than the outer portion thereof.

Referring to FIG. 2B, in the semiconductor package 1000 of one embodiment, a first upper substrate pads 132a of the upper substrate pads 130 of the first redistribution substrate 100 may have a multi-metal layer structure. For example, the first upper substrate pad 132a may include a Cu layer 132-1, a nickel (Ni) layer 132-2, and a gold (Au) layer 132-3. However, the number of layers of the first upper substrate pad 132a is not limited to three. In addition, the material of the metal layers of the first upper substrate pad 132a is not limited to the materials described above.

The first upper substrate pad 132a may have an upwardly convex upper surface. The convex upper surface of the first upper substrate pad 132a may be the same as described with reference to FIG. 2A. Accordingly, after being coupled to the first connection terminal 250 of the first semiconductor element 200, the upper surface of the first upper substrate pad 132a may have a shape in which at least a portion of the central portion thereof is slightly higher or thicker than the outer portion thereof. For example, the first upper substrate pad 132a may have a convex surface both before and after being coupled and affixed to the first connection terminal 250 of the first semiconductor element 200, but the height and/or amount of curvature before being coupled may be greater than the height and/or amount of curvature after being coupled and affixed.

The coupling roughness Ra may be formed on the upper surface of the first upper substrate pad 132a. In addition, the coupling roughness Ra may be formed on the Au layer 132-3, which is the uppermost metal layer of the first upper substrate pad 132a. The surface roughness of the upper surface of the first upper substrate pad 132a may be, for example, about 0.05 μm to about 0.07 μm. However, the surface roughness of the upper surface of the first upper substrate pad 132a is not limited to the numerical range described above.

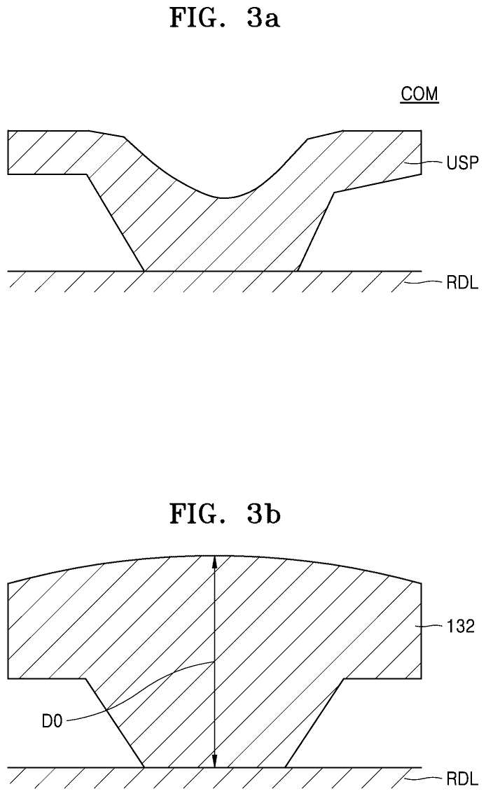

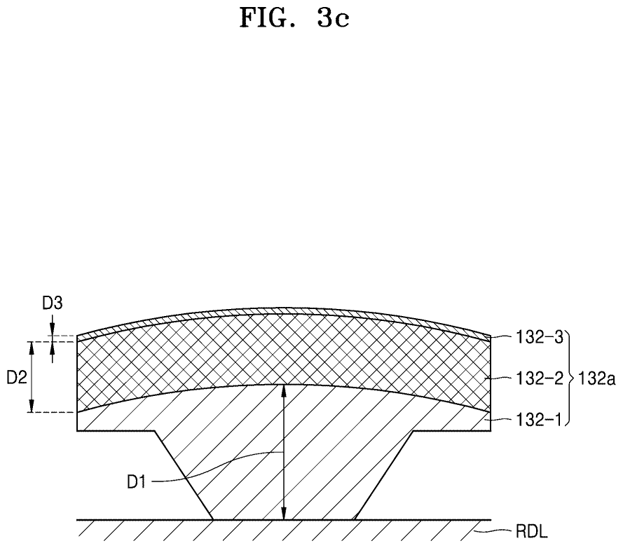

FIGS. 3A to 3C are cross-sectional views to describe the difference in shape between an upper substrate pad of a semiconductor package of a comparative example and the upper substrate pads of FIGS. 2A and 2B. In FIGS. 3B and 3C, the coupling roughness is omitted for convenience. Elements described above with reference to FIGS. 1A to 2B are briefly described or omitted.

Referring to FIG. 3A, an upper substrate pad USP of a semiconductor package COM of a comparative example may have a structure in which the central portion thereof is downwardly concave. Due to the shape of the upper substrate pad USP, when the upper substrate pad USP is coupled to the connection terminal of the semiconductor chip, there may be a portion that does not make contact or makes weak contact, and when the upper substrate pad USP is heated in a subsequent reflow process or the like, a non-wet defect may occur due to warpage of the semiconductor chip or the like.

For reference, the concave structure of the upper substrate pad USP of the semiconductor package COM of the comparative example may be due to a metal layer that is formed with a uniform thickness when the upper substrate pad USP is formed as a metal layer through a plating process. In addition, even when the upper substrate pad USP of the semiconductor package COM of the comparative example is formed in a multi-metal layer structure, all the multi-metal layers are formed in a uniform thickness, and thus, the upper substrate pad USP also has a concave structure.

Referring to FIGS. 3B and 3C, in the semiconductor package 1000 of the present embodiment, the first upper substrate pads 132 and 132a of the first redistribution substrate 100 may be formed through a via-filling process. Accordingly, the upper surfaces of the first upper substrate pads 132 and 132a may have a shape in which the central portion thereof is upwardly convex. The via-filling process may refer to a process of controlling the size and thickness of a metal layer plated inside a via-hole by changing the time and current density of a plating process when forming a metal layer of a substrate pad through plating. As a specific example, when forming a horizontal Cu-plated line, a melted Cu anode may be used and a reverse pulse plating rectifier may be applied to perform a via-filling process. When forming a vertical Cu-plated line, a via-filling process may be performed through agitation by controlling Cu ion concentration, performance of a polishing agent, temperature, etc.

In the case of the first upper substrate pad 132 of FIG. 3B, a via-filling process may be used to form a single metal layer, for example, a Cu layer. The first upper substrate pad 132 may have an upwardly convex upper surface. The upwardly convex upper surface may have a curved profile to be a curved surface. The thickness of the central portion of the first upper substrate pad 132 has a first, basic thickness DO, and the basic thickness DO may be, for example, 6 μm to 8 μm. However, the thickness of the central portion of the first upper substrate pad 132 is not limited to the numerical range described above. In addition, a thickness at the central portion of the first upper substrate pad 132 between the uppermost surface and a first plane on which the lower surface that contacts the first insulating layer PID1 is formed may be greater than a thickness at an outer portion between the upper surface and the first plane.

In the case of the first upper substrate pad 132a of FIG. 3C, the lowermost Cu layer 132-1 may be formed by a via-filling process, and the upper Ni layer 132-2 and Au layer 132-3 may be formed by a general plating process. Accordingly, the Cu layer 132-1 may include a pillar having a truncated reverse conical shape and a circular cap disposed on the pillar. Accordingly, the Ni layer 132-2 and the Au layer 132-3 may have a relatively uniform thickness.

The first upper substrate pad 132a may also have an upwardly convex upper surface. The upper surface may have a curved shape. A first thickness DI of the central portion of the Cu layer 132-1 may be, for example, 4 μm or more (e.g., between 4 μm and 8 μm). In addition, a second thickness D2 of the Ni layer 132-2 may be, for example, about 2 μm to about 3 μm. A third thickness D3 of the Au layer 132-3 may be, for example, 0.2 μm or less. However, the thickness of the central portion of the Cu layer 132-1 and the thicknesses of the Ni layer 132-2 and the Au layer 132-3 are not limited to the numerical ranges described above. On the other hand, the total thickness of the central portion of the first upper substrate pad 132a may be the same as or similar to the thickness of the central portion of the first upper substrate pad 132 of FIG. 3A. In some embodiments, at a central portion, the Cu layer 132-1 may be about 1.5 to 3 times the thickness of the first insulating layer PID1 (e.g., about 1.5, 2, 2.5, or 3 times the thickness), the thickness of the Ni layer 132-2 may be about 0.25 to about 0.5 times the thickness of the Cu layer 132-1 at the central portion, and the maximum thickness of the Au layer 132-3 may be about 0.05 to 0.2 times the thickness of the Ni layer 132-2.

FIGS. 4A to 4C are cross-sectional views of semiconductor packages according to embodiments. Elements described above with reference to FIGS. 1A to 3C are briefly described or omitted.

Referring to FIG. 4A, a semiconductor package 1000a of the present embodiment may differ from the semiconductor package 1000 of FIG. 1A in terms of a structure of a sealant 500a and a positional relationship between a first semiconductor element 200 and a second redistribution substrate 400. Specifically, in the semiconductor package 1000a of the present embodiment, the sealant 500a may cover the side surface and the upper surface of the first semiconductor element 200. Accordingly, a gap G may exist as thick as the sealant 500a disposed between the first semiconductor element 200 and the second redistribution substrate 400. The structure of the sealant 500a may be implemented by leaving a portion of the sealant on the upper surface of the first semiconductor element 200, without removing the entire sealant, during a back-grinding process of the sealant.

Referring to FIG. 4B, a semiconductor package 1000b of the present embodiment may differ from the semiconductor package 1000 of FIG. 1A in terms of a mounting position of a first semiconductor element 200. Specifically, in the semiconductor package 1000b of the present embodiment, the first semiconductor element 200 may be shifted to the right side in the x direction. Accordingly, more through posts 300a may be disposed on the left side in the x direction. For example, the through posts 300a may be divided into a first through post 300-1 disposed on the left side of the first semiconductor element 200 in the x direction and a second through post 300-2 disposed on the right side, and the number of first through posts 300-1 may be greater than the number of second through posts 300-2.

In some embodiments, the first semiconductor element 200 may be disposed adjacent to the right end in the x direction, and the through post may be disposed only on the left side of the first semiconductor element 200 in the x direction. In addition, in some embodiments, some through posts may be disposed on at least one side of the first semiconductor element 200 in the y direction.

Referring to FIG. 4C, a semiconductor package 1000c of the present embodiment may differ from the semiconductor package 1000 of FIG. 1A in that the first semiconductor element 200a includes two stacked semiconductor chips. Specifically, the first semiconductor element 200a may include a first semiconductor chip 200-1 at a lower portion and a second semiconductor chip 200-2 at an upper portion.

The first semiconductor chip 200-1 may be a logic semiconductor chip. For example, the first semiconductor chip 200-1 may be a modem chip that supports communication with the second semiconductor chip 200-2. However, the type of the first semiconductor chip 200-1 is not limited to the modem chip. For example, the first semiconductor chip 200-1 may include other types of integrated devices that support the operation of the second semiconductor chip 200-2. The first semiconductor chip 200-1 may include a multi-channel input/output (I/O) interface that exchanges memory signals with a second semiconductor element (see 700 of FIG. 5A). In addition, the first semiconductor chip 200-1 may include static random access memory (SRAM) that temporarily stores data.

The first semiconductor chip 200-1 may include a substrate 201-1, an active layer 210-1, chip pads 220-1, and through electrodes 240-1. The substrate 201-1, the active layer 210-1, and the chip pads 220-1 are the same as those of the first semiconductor element 200 of the semiconductor package 1000 described with reference to FIG. 1A.

The through electrodes 240-1 may extend in the vertical direction, i.e., the z direction, and pass through the substrate 201-1. The lower surface of each through electrode 240-1 may be connected to a wiring line of a multi-wiring layer of the active layer 210-1, and the upper surface of each through electrode 240-1 may be connected to a second connection terminal 250-2. Accordingly, the first semiconductor chip 200-1 may be connected to the second semiconductor chip 200-2 through the through electrodes 240-1 and the second connection terminals 250-2. In some embodiments, the through electrodes 240-1 may be directly connected to chip pads of the second semiconductor chip 200-2 through hybrid bonding (HB) or bonding using an anisotropic conductive film (ACF).

The through electrodes 240-1 have a structure that passes through silicon constituting the substrate 201-1, and thus, may be referred to as a through silicon via (TSV) or a through substrate via. For reference, each through electrode 240-1 may be divided into a via-first structure formed before the integrated circuit layer of the active layer 210-1 is formed, a via-middle structure formed after the integrated circuit layer is formed but before the multi-wiring layer of the active layer 210-1 is formed, and a via-last structure formed after the multi-wiring layer is formed. In FIG. 4C, the through electrode 240-1 may correspond to, for example, a via-middle structure. However, the inventive concept is not limited thereto. In the semiconductor package 1000c of the present embodiment, the through electrode 240-1 may have a via-first structure or a via-last structure.

The second semiconductor chip 200-2 may be mounted on the first semiconductor chip 200-1 through the second connection terminals 250-2 and an adhesive layer 270. In some embodiments, the second semiconductor chip 200-2 may be mounted on the first semiconductor chip 200-1 through HB or bonding using an ACF. For reference, the HB may refer to a combination of pad-to-pad bonding and insulator-to-insulator bonding. The ACF is an ACF that allows electricity to flow in only one direction and may refer to a conductive film made in a film state by mixing fine conductive particles into an adhesive resin.

The second semiconductor chip 200-2 may be a logic semiconductor chip. For example, the second semiconductor chip 200-2 may be similar to the first semiconductor element 200 of the semiconductor package 1000 of FIG. 1A. However, the second semiconductor chip 200-2 may not include integrated devices that perform functions such as communication. For example, the first semiconductor chip 200-1 and the second semiconductor chip 200-2 may correspond to the first semiconductor element 200 of the semiconductor package 1000 of FIG. 1A. The other parts of the second semiconductor chip 200-2 are the same as those of the first semiconductor element 200 of the semiconductor package 1000 described with reference to FIG. 1A.

FIGS. 5A and 5B are cross-sectional views of semiconductor packages according to embodiments. Elements described above with reference to FIGS. 1A to 4C are briefly described or omitted.

Referring to FIG. 5A, a semiconductor package 1000d of the present embodiment may differ from the semiconductor package 1000 of FIG. 1A in that the semiconductor package 1000d further includes a second semiconductor element 700. Specifically, the semiconductor package 1000d of the present embodiment may include a first redistribution substrate 100, a first semiconductor element 200, a through post 300, a second redistribution substrate 400, a sealant 500, a passive element 600, and a second semiconductor element 700. The first redistribution substrate 100, the first semiconductor element 200, the through post 300, the second redistribution substrate 400, the sealant 500, and the passive clement 600 are the same as those of the semiconductor package 1000 described with reference to FIG. 1A.

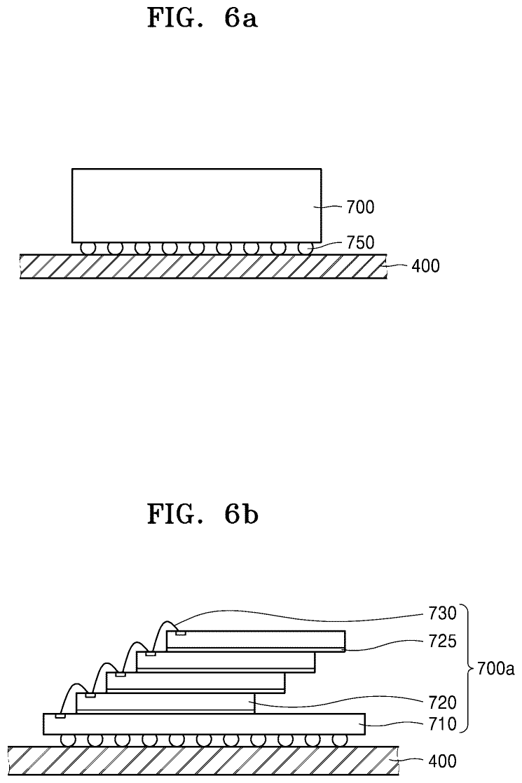

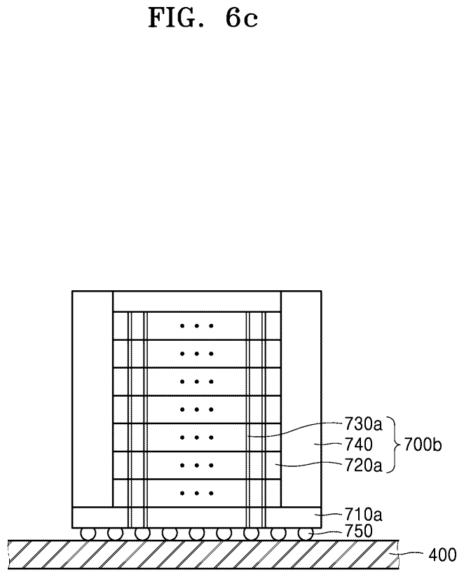

The second semiconductor clement 700 may be mounted on the second redistribution substrate 400 through a third connection terminal 750. The second semiconductor clement 700 may be a single chip or a package including a plurality of chips. For example, when the second semiconductor clement 700 is a single chip, the second semiconductor clement 700 may include one memory chip. When the second semiconductor clement 700 is a package, the second semiconductor clement 700 may include, for example, a plurality of memory chips. The memory chip of the second semiconductor clement 700 may include, for example, a volatile memory clement, such as dynamic random access memory (DRAM) or SRAM, or a non-volatile memory clement, such as flash memory. In the semiconductor package 1000d of the present embodiment, the memory chip of the second semiconductor element 700 may be, for example, a DRAM chip. However, the type of memory chip of the second semiconductor element 700 is not limited to the DRAM chip. The single chip structure or the package structure of the second semiconductor clement 700 is described in more detail below with reference to FIGS. 6A to 6C.

On the other hand, when the second semiconductor clement 700 is a package, the semiconductor package 1000d of the present embodiment may correspond to a POP structure. For example, in the semiconductor package 1000d of the present embodiment, the first redistribution substrate 100, the first semiconductor clement 200, the through post 300, and the second redistribution substrate 400 may constitute a lower package PKG1, and the second semiconductor clement 700 having the package structure may constitute an upper package PKG2. Accordingly, the semiconductor package 1000d of the present embodiment may have a POP structure in which the upper package PKG2 is stacked on the lower package PKG1.

Referring to FIG. 5B, a semiconductor package 1000e of the present embodiment may differ from the semiconductor package 1000d of FIG. 5A in that the semiconductor package 1000c further includes a heat dissipation block 800 and a first semiconductor element 200 is shifted to one side. Specifically, the semiconductor package 1000e of the present embodiment may include a first redistribution substrate 100, the first semiconductor clement 200, a through post 300a, a second redistribution substrate 400, a sealant 500, a passive element 600, a second semiconductor clement 700, and the heat dissipation block 800. The first redistribution substrate 100, the first semiconductor clement 200, the through post 300a, the second redistribution substrate 400, the sealant 500, and the passive clement 600 are the same as those of the semiconductor package 1000b described with reference to FIG. 4A. Accordingly, the first semiconductor element 200 may be shifted to the right side in the x direction, and most or all of the through posts 300a may be shifted to the left side of the first semiconductor clement 200 in the x direction.

The second semiconductor clement 700 may be substantially the same as the second semiconductor element 700 of the semiconductor package 1000d of FIG. 5A. However, the second semiconductor clement 700 may be shifted to the left side in the x direction. For example, the second semiconductor clement 700 may be disposed to correspond to the through post 300a on the left side in the x direction on the second redistribution substrate 400.

The heat dissipation block 800 may be disposed adjacent to the second semiconductor element 700 on the second redistribution substrate 400. For example, the heat dissipation block 800 may be disposed to correspond to the position of the first semiconductor clement 200 on the right side in the x direction on the second redistribution substrate 400. The heat dissipation block 800 may contribute to efficiently dissipating heat generated from the first semiconductor element 200. In some embodiments, the second redistribution substrate 400 may be disposed only on a portion corresponding to the second semiconductor element 700, and the heat dissipation block 800 may be directly disposed above at least a portion of the first semiconductor element 200.

The heat dissipation block 800 may be disposed on the second redistribution substrate 400 through an adhesive layer 810. The adhesive layer 810 may bond and fix the heat dissipation block 800 onto the second redistribution substrate 400. The adhesive layer 810 may include a material with high thermal conductivity so as to efficiently transfer heat from the first semiconductor clement 200 to the heat dissipation block 800. For example, the adhesive layer 810 may include a thermal interface material (TIM), a thermally conductive resin, a thermally conductive polymer, or a silicon oxide or a silicon nitride, such as SiO₂ or SiCN. The TIM may include a material with high thermal conductivity, i.e., a material with low thermal resistance, such as grease, tape, an elastomer-filled pad, or a phase transition material.

FIGS. 6A to 6C are cross-sectional views illustrating the structure of the semiconductor clement in the semiconductor package of FIGS. 5A or 5B in more detail. Elements described above with reference to FIGS. 1A to 5B are briefly described or omitted.

Referring to FIG. 6A, in the semiconductor package 1000d or 1000c of FIGS. 5A or 5B, the second semiconductor clement 700 may include one memory chip. The memory chip may include a volatile memory element, such as DRAM or SRAM, or a non-volatile memory element, such as flash memory. In the semiconductor package 1000d or 1000e of FIGS. 5A or 5B, the memory chip of the second semiconductor element 700 may include, for example, a DRAM chip. The second semiconductor element 700 may be mounted on the second redistribution substrate 400 through the third connection terminal 750. The third connection terminal 750 may include a metal pillar and solder or may include only solder.

Referring to FIG. 6B, in the semiconductor package 1000d or 1000e of FIGS. 5A or 5B, the second semiconductor element 700 may include a semiconductor package having a wire bonding structure. Specifically, a second semiconductor element 700a may include a package substrate 710 and a plurality of memory chips 720 stacked on the package substrate 710. The memory chip 720 may be mounted on the package substrate 710 in a wire bonding structure using an adhesive layer 725 and a wire 730. The memory chip 720 of the second semiconductor element 700a may include, for example, a volatile memory element, such as DRAM or SRAM, or a non-volatile memory element, such as flash memory. In the semiconductor package 1000d or 1000c of FIGS. 5A or 5B, the memory chip 720 of the second semiconductor element 700a may include, for example, a DRAM chip. On the other hand, the second semiconductor element 700a may include an internal sealant that seals the memory chip 720 and the wire 730 on the package substrate 710. However, in FIG. 6B, the inner sealant is omitted for convenience.

In FIG. 6B, four memory chips 720 are stacked on the package substrate 710, but the number of memory chips 720 is not limited to four. For example, three or less memory chips 720 or five or more memory chips 720 may be stacked on the package substrate 710. In addition, the memory chip 720 is not limited to a step structure and may be stacked on the package substrate 710 in a zigzag structure or a combined structure of a step structure and a zigzag structure. The third connection terminal 750 may be disposed on the lower surface of the package substrate 710. Accordingly, the second semiconductor element 700a of the package structure may also be mounted on the second redistribution substrate 400 through the third connection terminal 750.

Referring to FIG. 6C, in the semiconductor package 1000d or 1000e of FIGS. 5A or 5B, a second semiconductor element 700b may include a high bandwidth memory (HBM) package. Specifically, the second semiconductor element 700b may include a base chip 710a, a plurality of core chips 720a stacked on the base chip 710a, and an internal sealant 740. In addition, each of the base chip 710a and the core chips 720a may include a through electrode 730a. However, the uppermost core chip 720a among the core chips 720a may not include the through electrode 730a.

The base chip 710a may include logic elements. Accordingly, the base chip 710a may be a logic chip. The base chip 710a may be disposed below the core chips 720a and configured to integrate signals of the core chips 720a, transmit the signals to the outside, and transmit external signals and power to the core chips 720a. Accordingly, the base chip 710a may be referred to as a buffer chip or a control chip. On the other hand, each of the core chips 720a may be a memory chip. For example, each of the core chips 720a may be a DRAM chip. On the other hand, the core chip 720a may be stacked on the base chip 710a or the lower core chip 720a through pad-to-pad bonding, HB, bonding using a connection terminal, or bonding using an ACF. In FIG. 6C, eight core chips 720a are stacked on the base chip 710a, but the number of core chips 720a is not limited to eight. For example, seven or less core chips 720a or nine or more core chips 720a may be stacked on the base chip 410a.

The third connection terminal 750 may be disposed on the lower surface of the base chip 710a. Accordingly, the second semiconductor element 700b of the HBM package may also be mounted on the second redistribution substrate 400 through the third connection terminal 750. The core chips 720a on the base chip 710a may be sealed by the internal sealant 740. However, the upper surface of the uppermost core chip 720a among the core chips 720a may not be covered by the internal sealant 740. However, in other embodiments, the upper surface of the uppermost core chip 720a may be covered by the internal sealant 740.

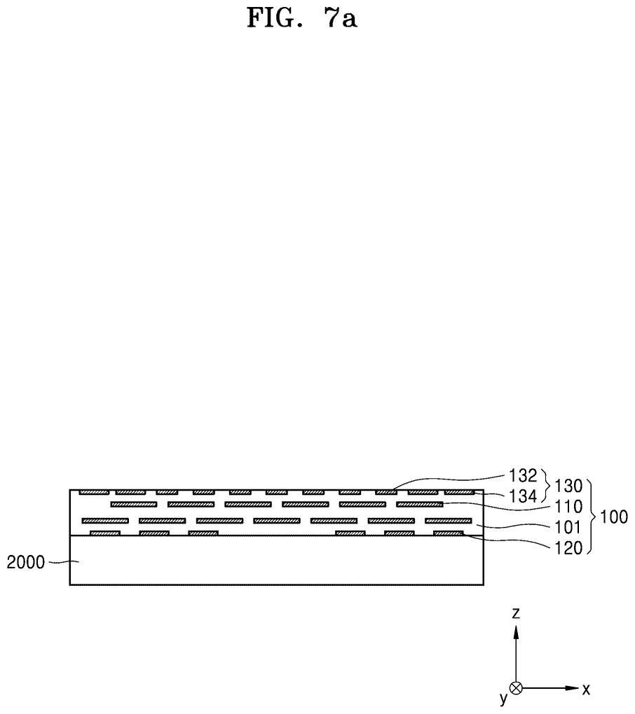

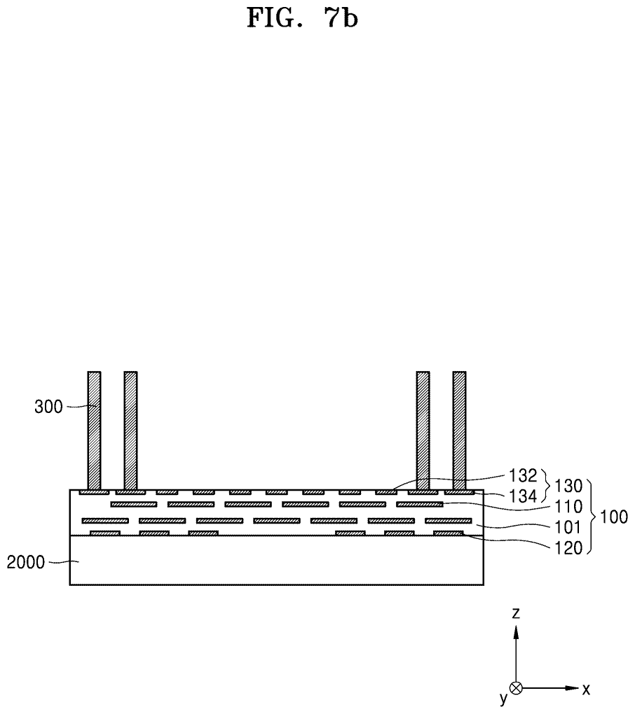

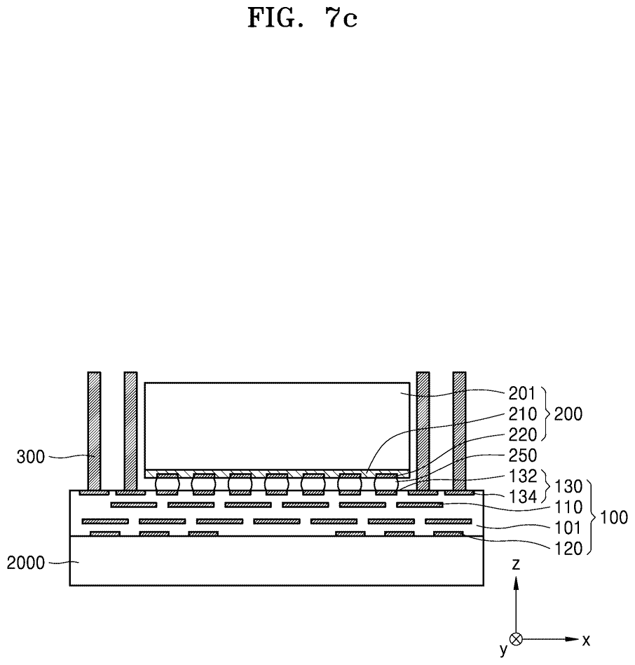

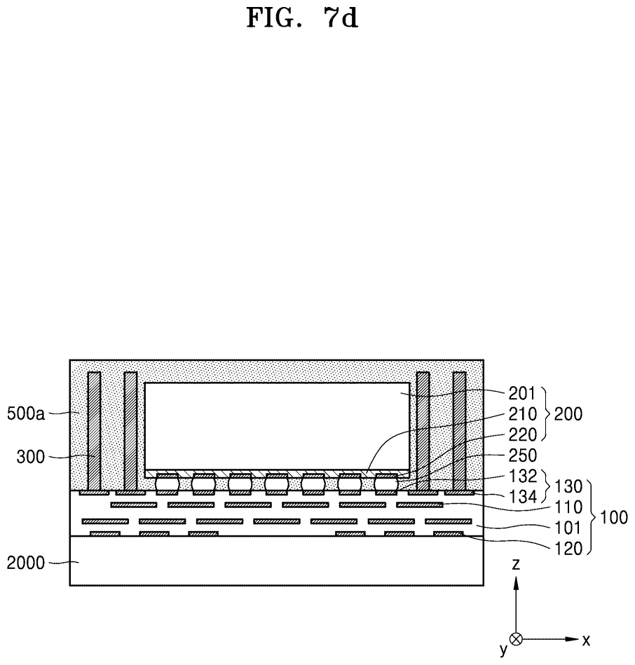

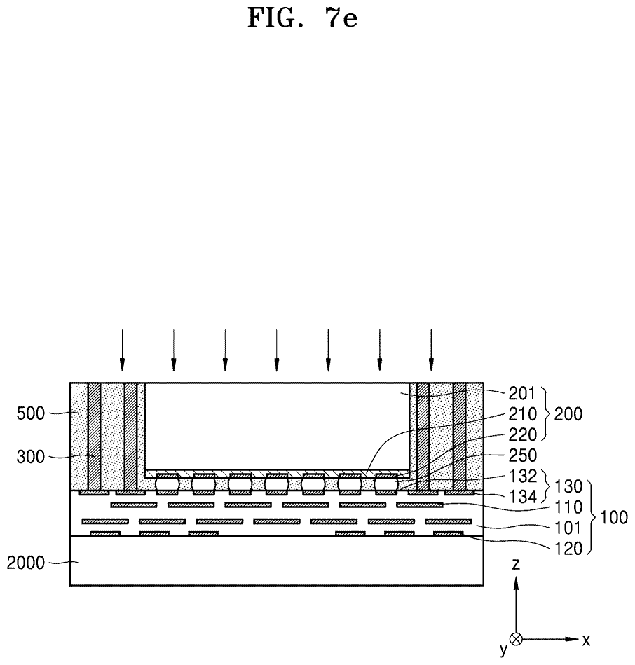

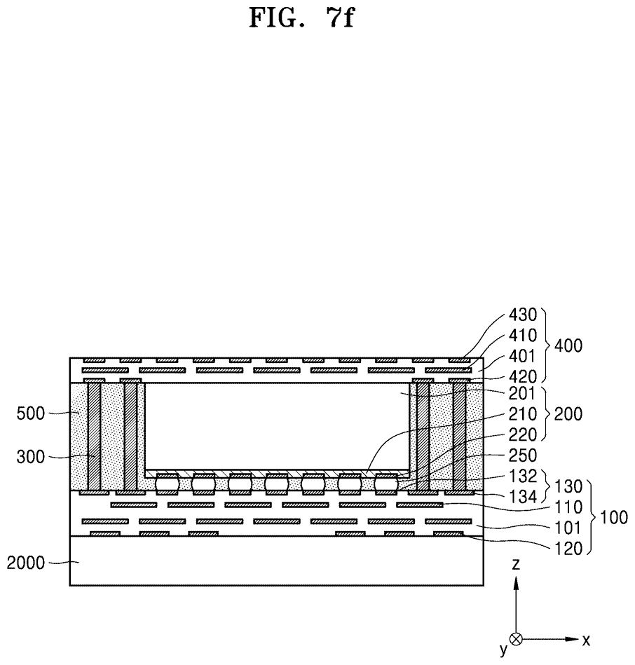

FIGS. 7A to 7F are cross-sectional views schematically illustrating a method of fabricating a semiconductor package, according to an embodiment. The following description is given with reference to FIGS. 1A and 1B together, and elements described with reference to FIGS. 1A to 6C are briefly described or omitted.

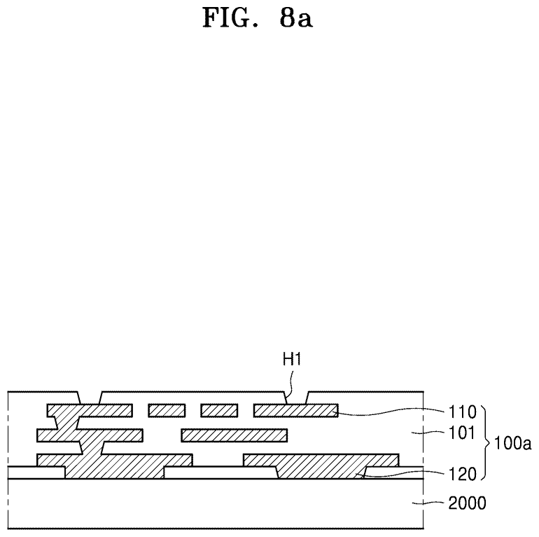

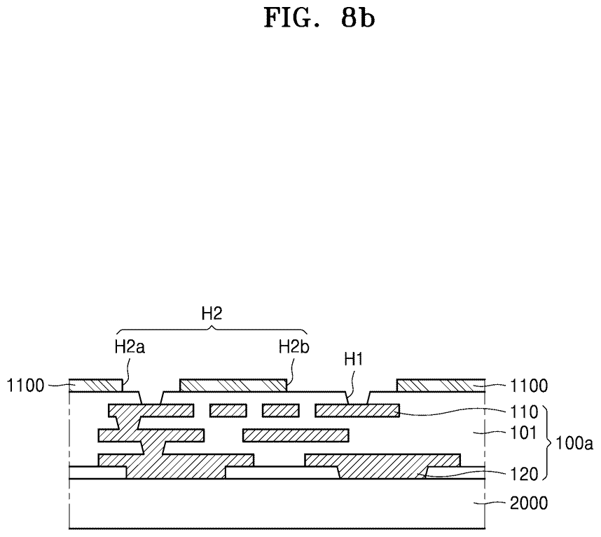

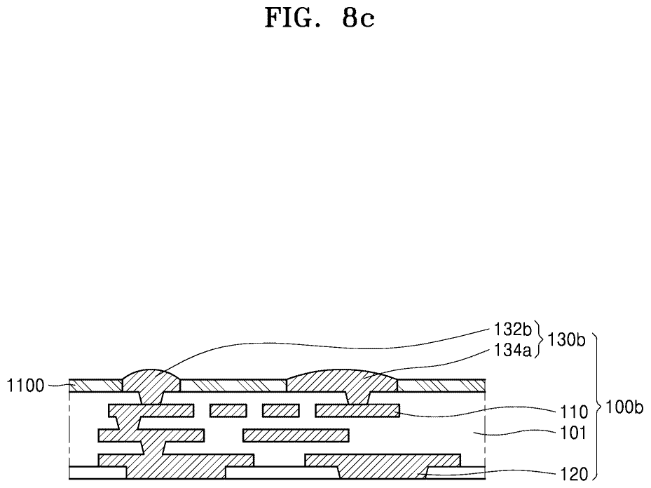

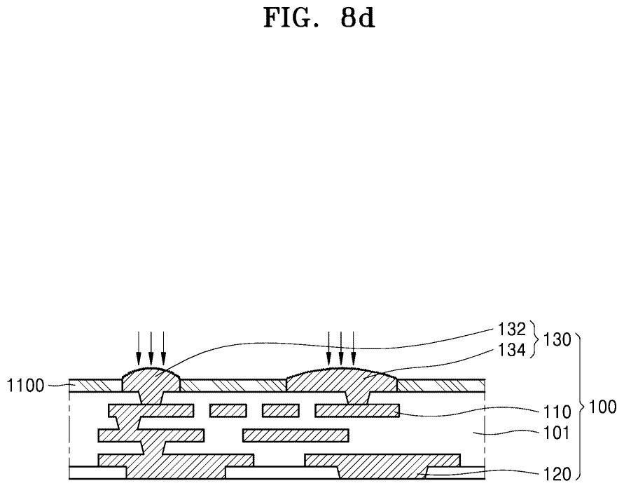

Referring to FIG. 7A, the method of fabricating a semiconductor package, according to the present embodiment, may include forming a first redistribution substrate 100. The first redistribution substrate 100 may be formed on a carrier substrate 2000. The first redistribution substrate 100 may be, for example, the first redistribution substrate 100 of the semiconductor package 1000 of FIG. 1A. Accordingly, the first redistribution substrate 100 may include a first substrate body 101, first redistribution lines 110, lower substrate pads 120, and upper substrate pads 130. In addition, the upper surface of the first upper substrate pads 132 coupled to the first connection terminals 250 of the first semiconductor element 200 among the upper substrate pads 130 may have a convex shape. In addition, a coupling roughness Ra may be formed on the upper surface of the first upper substrate pads 132. The method of forming the upper substrate pads 130 of the first redistribution substrate 100 is described in more detail below with reference to FIGS. 8A to 8D.

Referring to FIG. 7B, after the first redistribution substrate 100 is formed, a plurality of through posts 300 may be formed on the second upper substrate pads 134 among the upper substrate pads 130. As illustrated in FIG. 7B, the first upper substrate pads 132 may be disposed in the central portion in the x direction on the first redistribution substrate 100, and the second upper substrate pads 134 may be disposed at both outer portions in the x direction on the first redistribution substrate 100. Accordingly, the through posts 300 may be formed on both outer portions in the x direction on the first redistribution substrate 100. In addition, subsequently, the first semiconductor element 200 may be mounted on the central portion in the x direction on the first redistribution substrate 100. Though not shown, in some embodiments, through posts 300 may also be formed on outer portions in the y direction on the first redistribution substrate 100. The method of forming the through post 300 is described in more detail below with reference to FIGS. 9A to 9D.

In some embodiments, the first semiconductor element 200 may be shifted to one side, for example, to the right side, in the x direction on the first redistribution substrate 100. In this case, most or all of the second upper substrate pads 134 may be shifted to the left side in the x direction on the first redistribution substrate 100, and correspondingly, most or all of the through posts 300 may be formed to the left side in the x direction on the first redistribution substrate 100. After that, the semiconductor package 1000b of FIG. 4B may be fabricated through the processes of FIGS. 7C to 7F.

Referring to FIG. 7C, after the through post 300 is formed, the first semiconductor element 200 may be mounted on the first redistribution substrate 100 through the first connection terminal 250. For example, the first semiconductor element 200 may be mounted on the first redistribution substrate 100 through a TCB process. The first semiconductor element 200 may be disposed in the center in the x direction on the first redistribution substrate 100. The first connection terminals 250 may be coupled to the first upper substrate pads 132 of the upper substrate pads 130. As shown in

FIG. 7C, the height of the upper surface of the first semiconductor element 200 may be lower than the height of the upper surface of the through posts 300.

On the other hand, the first semiconductor element 200a in which two semiconductor chips are stacked may be mounted on the first redistribution substrate 100. In this case, the semiconductor package 1000c of FIG. 4C may be fabricated through the processes of FIGS. 7D to 7F

Referring to FIG. 7D, after the first semiconductor element 200 is mounted, a sealant 500a covering the first semiconductor element 200 and the through posts 300 may be formed. The sealant 500a may cover the side surface and the upper surface of each of the first semiconductor element 200 and the through posts 300. In addition, the sealant 500a may fill a space between the first semiconductor element 200 and the first redistribution substrate 100 and between the first connection terminals 250 on the lower surface of the first semiconductor element 200. The material of the sealant 500a is the same as the material of the sealant 500 of the semiconductor package 1000 described with reference to FIG. 1A.

Referring to FIG. 7E, after the sealant 500a is formed, the upper portion of the sealant 500a may be removed. The removing of the upper portion of the sealant 500a may be performed by, for example, a back-grinding process. By removing the upper portion of the sealant 500a, the upper surface of the first semiconductor element 200 and the upper surface of the through posts 300 may be exposed. In addition, after the upper portion of the sealant 500a is removed, the upper surfaces of the first semiconductor element 200, the through posts 300, and the sealant 500 may be substantially coplanar. By removing the upper portion of the sealant 500a, the sealant 500 of the semiconductor package 1000 of FIG. 1A may be formed.

On the other hand, in some embodiments, when removing the upper portion of the sealant 500a, only the upper surface of the through post 300 may be exposed and the upper surface of the first semiconductor element 200 may not be exposed. In this case, the semiconductor package 1000a of FIG. 4A may be fabricated.

Referring to FIG. 7F, after the sealant 500 is formed, a second redistribution substrate 400 may be formed above the first semiconductor element 200, the through posts 300, and the sealant 500. The second redistribution substrate 400 may be, for example, the second redistribution substrate 400 of the semiconductor package 1000 of FIG. 1A. In addition, the process of forming the second redistribution substrate 400 may be substantially the same as the process of forming the first redistribution substrate 100. However, a second redistribution line 410 of the second redistribution substrate 400 may be formed with a smaller number of layers than the first redistribution line 110 of the first redistribution substrate 100. Accordingly, the thickness of the second redistribution substrate 400 may be less than the thickness of the first redistribution substrate 100.

Thereafter, the carrier substrate 2000 may be separated from the first redistribution substrate 100 and the structure disposed thereabove, and an external connection terminal 150 and a passive element 600 may be formed on the lower surface of the first redistribution substrate 100, thereby fabricating the semiconductor package 1000 of FIG. 1A. In addition, the processes of FIGS. 7A to 7F may be performed at a wafer level or a panel substrate level. Accordingly, after the external connection terminal 150 and the passive element 600 are formed, the semiconductor package 1000 of FIG. 1A may be finally fabricated by singulation into a plurality of semiconductor packages through a sawing process.

FIGS. 8A to 8D are cross-sectional views illustrating the process of forming the first redistribution substrate of FIG. 7A in more detail and may all correspond to the cross-sectional view of FIG. 1B. Elements described above with reference to FIGS. 1A to 7F are briefly described or omitted.

Referring to FIG. 8A, in the method of fabricating a semiconductor package of the present embodiment, the method of forming the first redistribution substrate 100 may include forming a first through hole H1 on an initial first redistribution substrate 100a including a first substrate body 101, a first redistribution line 110, and a lower substrate pad 120 on a carrier substrate 2000.

The first through hole H1 may be formed by using a photo process. For example, the first substrate body 101 may include a PID and the first through hole H1 may be formed by patterning the uppermost insulating layer of the first substrate body 101, for example, the first insulating layer PID1, through a photo process. The first through hole H1 may expose at least a portion of the uppermost redistribution layer, for example, the first redistribution layer RDL1, among the first redistribution lines 110.

The first through hole H1 may have, for example, a truncated conical shape or a faceted conical shape. In addition, the cross-section of the first through hole H1 may have a reversed trapezoidal shape with a wide upper portion and a narrow lower portion, as illustrated in FIG. 8A. However, the shape of the first through hole H1 is not limited to the shapes described above.

Referring to FIG. 8B, after the first through hole H1 is formed, a photoresist (PR) pattern 1100 may be formed on the first substrate body 101. The PR pattern 1100 may include a second through hole H2. The second through hole H2 may open the first through hole H1. Also, as illustrated in FIG. 8B, the second through hole H2 may be wider than the first through hole H1.

The second through hole H2 may be divided into a second through hole H2a in a central portion and a second through hole H2b in an outer portion. The second through hole H2a in the central portion may be used to form the first upper substrate pad 132, and the second through hole H2b in the outer portion may be used to form the second upper substrate pad 134. It may be confirmed from FIG. 8B that the width of the second through hole H2b in the outer portion may be wider than the width of the second through hole H2a in the central portion.

Referring to FIG. 8C, after the PR pattern 1100 is formed, upper substrate pads 130 may be formed through a plating process. A via-filling process may be applied to the process of plating the upper substrate pads 130. Accordingly, each upper substrate pad 130 may have an upwardly convex upper surface. In FIG. 8C, both the first and second upper substrate pads 132 and 134 may have convex upper surfaces. However, in some embodiments, the process of plating the first upper substrate pad 132 and the second upper substrate pad 134 may be performed separately so that only the first upper substrate pad 132 has a convex upper surface.

In some embodiments, when the upper substrate pads 130 have a multi-metal layer structure like the first upper substrate pad 132a of FIG. 2B, a via-filling process may be applied to the lowermost Cu layer 132-1 to form a convex upper surface. The upper Ni layer 132-2 and the Au layer 132-3 may be formed with a uniform thickness through a general plating process.

Referring to FIG. 8D, after the upper substrate pad 130 is formed, a coupling roughness Ra may be formed on the upper surface of the upper substrate pad 130. The coupling roughness Ra may be formed by a roughness treatment that includes, for example, treating the upper surface of the upper substrate pad 130 with a chemical agent for roughness formation (e.g., CZ8100 available from MEC). The coupling roughness Ra may be formed on both the upper surfaces of the first and second upper substrate pads 132 and 134. However, in some embodiments, by performing the process of forming roughness only on the first upper substrate pad 132, the coupling roughness Ra may be formed only on the upper surface of the first upper substrate pad 132. By forming the coupling roughness Ra on the upper surface of the upper substrate pads 130, the first redistribution substrate 100 may be completed.

FIGS. 9A to 9D are cross-sectional views illustrating the process of forming the through post of FIG. 7B in more detail. Elements described above with reference to FIGS. 1A to 8D are briefly described or omitted.

Referring to FIG. 9A, after the completion of the first redistribution substrate 100, a PR layer 1200 may be formed on the first redistribution substrate 100. The PR layer 1200 may be formed through, for example, spin coating.

Referring to FIG. 9B, after the PR layer 1200 is formed, a light exposure process may be performed thereon. The light exposure process may be performed by using a mask including a specific pattern. For example, light may be transmitted through a transparent portion of a transparent mask to radiate light onto a predefined portion of the PR layer 1200. The chemical properties of the portion of the PR layer 1200 irradiated with light may be changed. For example, after the light exposure process, the PR layer 1200a may be divided into a light exposed portion 1210 and a light unexposed portion 1220. It may be confirmed from FIG. 9B that the light exposed portion 1210 may be disposed above the second upper substrate pad 134 of the first redistribution substrate 100.

Referring to FIG. 9C, after the exposure process, a development process may be performed on the PR layer 1200a. In the development process, for example, the light exposed portion 1210 may be removed. For example, the PR layer 1200a may include a positive PR. A PR pattern 1200b may be formed by removing the light exposed portion 1210 through the development process. The PR pattern 1200b may include a plurality of third through holes H3. The upper surface of the second upper substrate pad 134 may be exposed at the bottom surfaces of the third through holes H3. On the other hand, a negative PR may be used according to an embodiment. When the negative PR is used, light unexposed portions may be removed in the development process.

Referring to FIG. 9D, a through posts 300 may be formed in the third through holes H3 through a plating process. The through posts 300 may include or may be, for example, Cu. However, the material of the through posts 300 is not limited to Cu.

While the inventive concept has been particularly shown and described with reference to embodiments thereof, it will be understood that various changes in form and details may be made therein without departing from the spirit and scope of the following claims.

What is claimed is:

1. A semiconductor package comprising:
a first redistribution substrate comprising a plurality of upper substrate pads including a first upper substrate pad;
a first semiconductor device mounted on the first redistribution substrate and connected to the first redistribution substrate through bonding of the first upper substrate pad to a first connection terminal;
a plurality of conductive through posts disposed on the first redistribution substrate outside of the first semiconductor device from a plan view; and
a second redistribution substrate disposed on the first semiconductor device and the plurality of conductive through posts,
wherein the first upper substrate pad has a convex upper surface and has a coupling roughness formed on an upper surface thereof.

2. The semiconductor package of claim 1, wherein the first upper substrate pad comprises a multi-metal layer structure, and
the coupling roughness is formed on an uppermost metal layer of the multi-metal layer structure.

3. The semiconductor package of claim 2, wherein the multi-metal layer structure comprises a copper (Cu) layer, a nickel (Ni) layer, and a gold (Au) layer, which are sequentially stacked in an upward direction toward the first semiconductor device.

4. The semiconductor package of claim 3, wherein the Cu layer comprises a pillar having a truncated reverse conical shape and a circular cap disposed on the pillar, and
the circular cap has a shape in which a central portion thereof is thicker than an outer portion thereof and has an upwardly convex shape.

5. The semiconductor package of claim 4, wherein:
each of the Ni layer and the Au layer has a uniform thickness,
the Cu layer has a thickness of 4 μm or more in a central portion thereof,
the Ni layer has a thickness of 2 μm to 3 μm, and
the Au layer has a thickness of 0.2 μm or less.

6. The semiconductor package of claim 1, wherein the coupling roughness of the first upper substrate pad is about 0.05 μm to about 0.07 μm.

7. The semiconductor package of claim 1, further comprising a second semiconductor device mounted on the second redistribution substrate.

8. The semiconductor package of claim 7, further comprising a heat dissipation block disposed adjacent to the second semiconductor device on the second redistribution substrate,
wherein, when viewed from a first horizontal direction:
the first semiconductor device is disposed on a right side in a second horizontal direction on the first redistribution substrate,
a set of posts of the conductive through posts are disposed adjacent to the first semiconductor device on a left side in the second horizontal direction on the first redistribution substrate,
the second semiconductor device is disposed on a left side in the second horizontal direction on the second redistribution substrate to correspond to the set of posts, and
the heat dissipation block is disposed on a right side in the second horizontal direction on the second redistribution substrate to correspond to the first semiconductor device.

9. The semiconductor package of claim 7, wherein:
the first semiconductor device comprises a logic chip, and
the second semiconductor device comprises a memory chip or a memory package.

10. The semiconductor package of claim 1, wherein:
the first semiconductor device has a structure in which two semiconductor chips are stacked, and
a lower semiconductor chip of the two semiconductor chips comprises a through electrode.

11. The semiconductor package of claim 1, further comprising a second upper substrate pad bonded to a first conductive through post of the plurality of conductive through posts,
wherein when viewed from a first horizontal direction, an upper surface of the second upper substrate pad is wider than an upper surface of the first upper substrate pad.

12. A semiconductor package comprising:
a first redistribution substrate comprising a plurality of upper substrate pads;
a first semiconductor device mounted on the first redistribution substrate and electrically connected to the first redistribution substrate through a first connection terminal disposed on the first redistribution substrate;
a conductive through post disposed on the first redistribution substrate to be adjacent to the first semiconductor device;
a sealant that seals the first semiconductor device and the conductive through post on the first redistribution substrate;
a second redistribution substrate disposed on the first semiconductor device, the conductive through post, and the sealant; and
a second semiconductor device mounted on the second redistribution substrate,
wherein the plurality of upper substrate pads comprise a first upper substrate pad bonded to the first connection terminal and a second upper substrate pad bonded to the conductive through post, and
the first upper substrate pad has a convex upper surface and has a coupling roughness formed on an upper surface thereof.

13. The semiconductor package of claim 12, wherein:
the first upper substrate pad comprises a copper (Cu) layer, a nickel (Ni) layer, and a gold (Au) layer, which are sequentially stacked in an upward direction toward the first semiconductor device,
the Cu layer comprises a pillar having a truncated reverse conical shape and a circular cap disposed on the pillar,
the circular cap has a shape in which a central portion thereof is thicker than an outer portion thereof and has an upwardly convex shape, and
each of the Ni layer and the Au layer has a uniform thickness.

14. The semiconductor package of claim 12, further comprising a heat dissipation block disposed adjacent to the second semiconductor device on the second redistribution substrate,
wherein the conductive through post passes through the sealant and connects the first redistribution substrate to the second redistribution substrate,
wherein the second semiconductor device is disposed on a left side in a first direction on the second redistribution substrate to correspond to the conductive through post, and
wherein the heat dissipation block is disposed on a right side in the first direction on the second redistribution substrate to correspond to the first semiconductor device.

15. The semiconductor package of claim 12, wherein:
the first semiconductor device comprises one logic chip or two logic chips, and
the second semiconductor device comprises a memory chip or a memory package.

16. A semiconductor package comprising:
a first redistribution substrate comprising a plurality of upper substrate pads including a first upper substrate pad;
a first semiconductor device mounted on the first redistribution substrate and connected to the first redistribution substrate through bonding of the first upper substrate pad to a first connection terminal;
a conductive through post disposed on the first redistribution substrate outside of the first semiconductor device as viewed from a plan view;
a second redistribution substrate disposed on the first semiconductor device and the conductive through post; and
a second semiconductor device mounted on the second redistribution substrate,
wherein the first redistribution substrate comprises a substrate body, multilayer redistribution lines within the substrate body, and the plurality of upper substrate pads, and
wherein the first upper substrate pad is connected to an uppermost redistribution line among the multilayer redistribution lines, has a convex upper surface, and has a coupling roughness formed on an upper surface thereof.

17. The semiconductor package of claim 16, wherein the first upper substrate pad comprises a copper (Cu) layer, a nickel (Ni) layer, and a gold (Au) layer, which are sequentially stacked in an upward direction toward the first semiconductor device, and
a coupling roughness is formed on the Au layer.

18. The semiconductor package of claim 17, wherein:
the Cu layer comprises a pillar having a truncated reverse conical shape and a circular cap disposed on the pillar,
the circular cap has a shape in which a central portion thereof is thicker than an outer portion thereof and has an upwardly convex shape, and
each of the Ni layer and the Au layer has a uniform thickness.

19. The semiconductor package of claim 18, wherein:
the substrate body comprises multiple photo-imageable dielectric (PID) layers, and
a through hole exposing the uppermost redistribution line is formed in an uppermost PID layer among the multiple PID layers, and the pillar is disposed in a structure that is inserted into the through hole.

20. The semiconductor package of claim 16, further comprising a heat dissipation block disposed on the second redistribution substrate,
wherein:
the first semiconductor device is a logic device and is disposed on a right side in a first direction on the first redistribution substrate,
the conductive through post is disposed adjacent to the logic device on a left side in the first direction on the first redistribution substrate,
the second semiconductor device is a memory device disposed on a left side in the first direction on the second redistribution substrate to correspond to the conductive through post, and
the heat dissipation block is disposed on a right side in the first direction on the second redistribution substrate to correspond to the first semiconductor device.
